(19) United States
(12) Patent Application Publication
(10) Pub. No.: US 2007/0096078 A1
(43) Pub. Date: May 3, 2007

(54) Organic-inorganic hybrid nanocomposite thin films for high-powered and/or broadband photonic device applications and methods for fabricating the same and photonic device having the thin films

(76) Inventors: Myung Hyun Lee, Daejeon-city (KR); Jung Jin Ju, Daejeon-city (KR); Min Su Kim, Daejeon-city (KR); Seung Koo Park, Daejeon-city (KR); Woon Jin Chung, Seoul (KR); Hong seok Seo, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/356,004

(22) Filed: Feb. 16, 2006

(30) Foreign Application Priority Data
Oct. 28, 2005 (KR) 10-2005-0102484

(51) Int. Cl. H01L 31/00; H01L 33/00

(52) U.S. Cl. 257/14; 257/103; 257/E29.071

(57) ABSTRACT

An organic-inorganic hybrid nanocomposite thin film for a high-powered and/or broadband photonic device having an organic ligand-coordinated semiconductor quantum dot layer, a photonic device having the same, and a method of fabricating the same are provided. The organic-inorganic hybrid nanocomposite thin film is composed of a stack structure comprising a polymer layer and an organic ligand-coordinated semiconductor quantum dot layer self-assembled on the polymer layer, or composed of a first composite thin film comprising a first polymer layer pattern having a first hole, and an organic ligand-coordinated first semiconductor quantum dot layer pattern filling the first hole. The organic-inorganic hybrid nanocomposite thin film may be formed by spin-coating a semiconductor quantum dot solution and a polymer solution alternately to be stacked by one layer so as to form a multi-layered organic thin film composed of a plurality of layers. The hybrid nanocomposite thin film for a photonic device may be provided by physically coupling a high concentration and broadband semiconductor quantum dot layer and a polymer layer so as to realize a photonic device with high power, broadband, high brightness, and high sensibility, and a flexible photonic device may be also provided.

### CROSS-REFERENCE TO RELATED PATENT APPLICATION

This application claims the benefit of Korean Patent Application No. 10-2005-0102484, filed on Oct. 28, 2005, in the Korean Intellectual Property Office, the disclosure of which is incorporated herein in its entirety by reference.

### BACKGROUND OF THE INVENTION

1. Field of the Invention

The present invention relates to a thin film for high-powered and/or broadband photonic device, a photonic device having the same, and a method of fabricating the same, and more particularly, to an organic-inorganic hybrid nanocomposite thin film formed using an organic-inorganic nanocomposite material having semiconductor quantum dots and polymer, a photonic device having the same, and a method of fabricating the organic-inorganic hybrid nanocomposite thin film.

2. Description of the Related Art

An organic-inorganic hybrid nanocomposite material, in which semiconductor quantum dots for a photonic device and polymer are bonded to each other, has been developed mostly by a chemical method not by a physical method. Methods of forming the organic-inorganic hybrid nanocomposite material by a chemical method may be classified into four kinds.

A first method is to form a thin film by chemically bonding an organic-inorganic hybrid quantum dot semiconductor solution and a polymer solution concurrently (Yongbin Zhao et al., Synthesis and characterization of PbS/modified hyperbranched polyester nanocomposite hollow spheres at room temperature, Materials Letters, vol. 59, p. 686, 2005). However, the method has a disadvantage of being difficulty in forming a thin film through a spin-coating or the like while the chemical solution may be easily prepared. Furthermore, even though a thin film is formed, the thin film may be hardly formed with a well-scattered good quality.

A second method is to prepare a semiconductor quantum dot solution and a conductive polymer solution separately, and use the solutions just by mixing the two solutions. As examples of materials used in this method, a thin film is formed by spin-coating mixed two solutions and is just thermally hardened (Nir Tessler et al., Efficient Near-Infrared Polymer Nanocrystal Light-Emitting Diodes, Science vol. 295, p. 1506, 2002), and a material eluted to a surface of a thin film and arrayed by semiconductor quantum dots by saturation solubility and phase segregation during a thermal hardening (Jonathan S Steckel et al., 1.3 μm to 1.55 μm Tunable Electroluminesence from PbSe Quantum Dots Embedded within an Organic Device, Advanced Materials, vol. 15, No. 21 p. 1862, 2003). The method allows formation of a low concentration semiconductor quantum dot thin film by a saturation solubility inside the thin film, but it is very difficult to increase a concentration of quantum dots, and also very difficult to array semiconductor quantum dots appropriately or stack into a plurality of layers.

A third method is to prepare a semiconductor quantum dot solution and a conductive polymer solution separately and mix them to passivation-treat surfaces of semiconductor quantum dots using a ligand exchange method and concurrently, make a composite material solution. The mixed solution is used as a material for a photonic device by forming into a thin film using a spin-coating or the like, or optically hardening using ultraviolet rays. However, the method also allows formation of a low concentration semiconductor quantum dot thin film by a saturation solubility inside the thin film, but it is very difficult to increase a concentration of quantum dots, and has many defects, such as requiring that basic polymer must have an amine group to cause the ligand exchange method.

A fourth method is to spin-coat a conductive polymer solution and a semiconductor quantum dot solution alternately by one layer. In the method, a polymer layer and a semiconductor quantum dot layer are formed just by a spin-coating (Sumit Chaudhary et al., Trilayer hybrid polymer-quantum dot light-emitting diodes, Applied Physics Letters, vol. 84, no. 15. p. 2925, 2004). However, the semiconductor quantum dot layer formed by the method is just formed of one kind of an arbitrarily-arrayed semiconductor quantum dot layer so that it is very difficult to realize a high concentration and a broad band.

In order to form a semiconductor quantum dot layer in the case of a pure semiconductor quantum dot thin film material not an organic-inorganic nanocomposite material, growth systems such as molecular beam epitaxy (MBE), metal-organic chemical vapor deposition (MOCVD) are used, and a Stranski-Kranstanow (SK) growth mode is used to grow the thin film, and a rapid thermal annealing method is used to form a semiconductor quantum dot layer. The semiconductor quantum dot layers are reportedly stacked by 30 layers to increase a concentration of the semiconductor quantum dots (K. Stewart et al., Influence of rapid thermal annealing on a 30 stack InAs/GaAs quantum dot infrared photodetector, Journal of Applied Physics, Vol. 94, No. 8. p. 5283, 2003). However, a concentration (density) of one quantum dot layer is low, just as much as a height of one quantum dot, since quantum dots are arbitrarily distributed on a two-dimensional plane area.

### SUMMARY OF THE INVENTION

The present invention provides an organic-inorganic hybrid nanocomposite thin film for high-powered and/or broadband photonic device having a flexibility and suitable to used for photonic devices, such as a high-powered and broadband light emitting diode (LED), an optical receiver device, an optical sensor, and having high concentration and broadband semiconductor quantum dots and polymer physically coupled.

The present invention also provides a high-powered and broadband photonic device having a high quality organic-inorganic hybrid nanocomposite thin film material, in which high concentration and broadband semiconductor quantum dots and polymer are physically coupled.

The present invention also provides a method of forming an organic-inorganic hybrid nanocomposite thin film for a high-powered and/or broadband photonic device having a flexibility and suitable to used for photonic devices, such as a high-powered and broadband LED, an optical receiver device, an optical sensor, and a sun battery, and having high concentration and broadband semiconductor quantum dots and polymer physically coupled.

According to an aspect of the present invention, there is provided an organic-inorganic hybrid nanocomposite thin film for a photonic device composed of a stack structure comprising a polymer layer and an organic ligand-coordinated semiconductor quantum dot layer self-assembled on the polymer layer.

The polymer layer and the semiconductor quantum dot layer may have different properties selected from a polarity and a nonpolarity respectively.

The stack structure may comprise a plurality of polymer layers and a plurality of semiconductor quantum dot layers, which are alternately and sequentially stacked by one layer.

The plurality of semiconductor quantum dot layers may have a same size of quantum dots, or the plurality of semiconductor quantum dot layers may have at least two semiconductor quantum dot layers, quantum dots of which have different sizes.

According to another aspect of the present invention, there is provided an organic-inorganic hybrid nanocomposite thin film for a photonic device composed of a first composite thin film comprising a first polymer layer pattern having a first hole, and an organic ligand-coordinated first semiconductor quantum dot layer pattern filling the first hole.

The first polymer layer pattern and the first semiconductor quantum dot layer pattern may be formed on a same plane at a same height level. Further, the organic-inorganic hybrid nanocomposite thin film may comprise a first polymer thin film formed on the first composite thin film to cover the first polymer layer pattern and the first semiconductor quantum dot layer pattern concurrently.

The organic-inorganic hybrid nanocomposite thin film may further comprise a second composite thin film formed on the first polymer thin film and opposite to the first composite thin film, and comprising a second polymer layer pattern having a second hole, and an organic ligand-coordinated second semiconductor quantum dot layer pattern filling the second hole.

The first semiconductor quantum dot layer pattern and the second semiconductor quantum dot layer pattern may have a same size of quantum dots, or the first semiconductor quantum dot layer pattern and the second semiconductor quantum dot layer pattern may have different sizes of quantum dots respectively.

According to another aspect of the present invention, there is provided a photonic device comprising a first electrode; a second electrode; and a hole transmitting layer, a luminescence layer, and an electron transmitting layer, which are sequentially stacked between the first electrode and the second electrode. The luminescence layer may be composed of any one of the organic-inorganic hybrid nanocomposite thin films for a high-powered and/or broadband photonic device according to the present invention as described above.

According to another aspect of the present invention, there is provided a method of forming an organic-inorganic hybrid nanocomposite thin film for a photonic device comprising forming a polymer layer on a substrate. An organic ligand-coordinated semiconductor quantum dot solution is spin-coated on the polymer layer, thereby forming a self-assembled semiconductor quantum dot layer on the polymer layer.

The forming of the polymer layer and the forming of the semiconductor quantum dot layer may be repeatedly performed by plural times, thereby forming a stack structure comprising a plurality of polymer layers and a plurality of semiconductor quantum dot layers, which are alternately and sequentially stacked by one layer. The plurality of semiconductor quantum dot layers may have a same size of quantum dots, or the plurality of semiconductor quantum dot layers may have at least two semiconductor quantum dot layers, quantum dots of which have different sizes.

In order to realize a flexible photonic device, the substrate may be removed from the polymer layer.

According to another aspect of the present invention, there is provided a method of forming an organic-inorganic hybrid nanocomposite thin film for a photonic device comprising forming a first polymer layer on a substrate. The first polymer layer is patterned, thereby forming a first polymer layer pattern having a predetermined-shaped first hole. By spin-coating an organic ligand-coordinated semiconductor quantum dot solution on a first polymer layer pattern, a first semiconductor quantum dot layer pattern is formed inside the first hole.

The method may further comprise forming a first polymer thin film covering the first polymer layer pattern and the first semiconductor quantum dot layer pattern concurrently. The method may further comprise forming a second polymer layer on the first polymer thin film; patterning the second polymer layer, thereby forming a second polymer layer pattern having a predetermined-shaped second hole; and spin-coating an organic ligand-coordinated semiconductor quantum dot solution on the second polymer layer pattern, thereby forming a second semiconductor quantum dot layer pattern inside the second hole. The first semiconductor quantum dot layer pattern and the second semiconductor quantum dot layer pattern may be formed to have a same size of quantum dots, or may be formed to have different sizes of semiconductor quantum dots respectively.

The organic-inorganic hybrid nanocomposite thin film according to the present invention may be formed as a multi-layered semiconductor quantum dot layer structure by preparing a previously-mixed quantum dot semiconductor solution, and spin-coating the solution. Further, the organic-inorganic hybrid nanocomposite thin film according to the present invention may be used as a luminescence layer for a photonic device, and may realize a photonic device such as an LED, an optical receiver, an optical sensor, and a sun battery with high power, broad band, high brightness, and high sensibility. Particularly, by employing a flexible substrate or by forming the organic-inorganic hybrid nanocomposite thin film according to the present invention and removing a substrate, a flexible photonic device can be provided.

### BRIEF DESCRIPTION OF THE DRAWINGS

The above and other features and advantages of the present invention will become more apparent by describing in detail exemplary embodiments thereof with reference to the attached drawings in which:

FIG. 1 is a partial perspective view illustrating a structure of an organic-inorganic hybrid nanocomposite thin film for a high-powered and/or broadband photonic device according to an embodiment of the present invention;

FIG. 2A is a transmission electron microscope (TEM) image illustrating a semiconductor quantum dot layer of forming an organic-inorganic hybrid nanocomposite thin film for a high-powered and/or broadband photonic device;

FIG. 2B is a schematic diagram illustrating an alignment state of PbSe quantum dots having a hexagonal array structure in the semiconductor quantum dot layer of FIG. 2A;

FIG. 2C is a TEM image illustrating a PbSe quantum dots layer of a hexagonal array structure having a two-layered close packed structure;

FIG. 2D is a schematic diagram illustrating an alignment state of a PbSe quantum dots layer of a hexagonal array structure having a four-layered face centered cubic (FCC) close packed structure;

FIG. 3 is a partial perspective view illustrating a structure of an organic-inorganic hybrid nanocomposite thin film for a high-powered and/or broadband photonic device according to another embodiment of the present invention;

FIG. 4 is a partial perspective view illustrating a structure of an organic-inorganic hybrid nanocomposite thin film for a high-powered and/or broadband photonic device according to another embodiment of the present invention;

FIG. 5 is a partial perspective view illustrating a structure of an organic-inorganic hybrid nanocomposite thin film for a high-powered and/or broadband photonic device according to another embodiment of the present invention;

FIG. 6 is a partial perspective view illustrating a structure of an organic-inorganic hybrid nanocomposite thin film for a high-powered and/or broadband photonic device according to another embodiment of the present invention;

FIG. 7 is a graph illustrating a photoluminescence (PL) intensity characteristic with respect to an organic-inorganic hybrid nanocomposite thin film according to an embodiment of the present invention;

FIG. 8 is a TEM image examined after spin-coating an oleate ligand-coordinated PbSe quantum dot solution having various average diameters;

FIG. 9 is a graph illustrating a PL intensity characteristic in accordance with an average diameter of a PbSe quantum dot;

FIG. 10 is a sectional view illustrating a schematic structure of a photonic device according to an embodiment of the present invention; and

FIGS. 11A through 11D are sectional views illustrating an example of fabricating a photonic device in accordance with processing sequences according to another embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

Exemplary embodiments of the present invention provide a hybrid nanocomposite thin film having semiconductor quantum dot layer/polymer layer for a high-powered and broadband flexible photonic device, and a method of fabricating the same, using a simple spincoating method and a principle that a nonpolar (or polar) substance thin film is well formed on a polar (or nonpolar) substance thin film.

Exemplary embodiments of the present invention provide an organic-inorganic hybrid nanocomposite thin film comprising a first thin film composed of a polymer layer by alternately and sequentially spin-coating a nonpolar polymer solution and a polar organic ligand-coordinated semiconductor quantum dot solution, and a second thin film composed of a self-assembled semiconductor quantum dot layer.

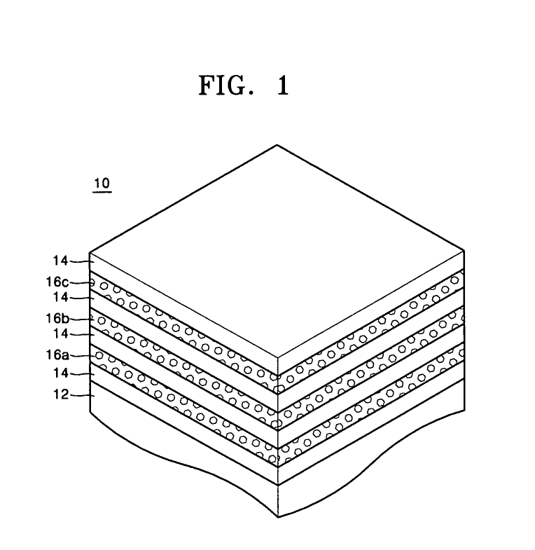

FIG. 1 is a partial perspective view illustrating a structure of an organic-inorganic hybrid nanocomposite thin film 10 for a high-powered and/or broadband photonic device according to an embodiment of the present invention.

Referring to FIG. 1, an organic-inorganic hybrid nanocomposite thin film 10 for a high-powered and/or broadband photonic device according to an embodiment of the present invention comprises a plurality of first thin films 14 composed of a polymer layer formed on a substrate 12, and a plurality of second thin films 16a, 16b, and 16c composed of a self-assembled semiconductor quantum dot layer formed on the first thin film 14, in which the first thin films 14 and the second thin films 16a, 16b, and 16c are alternately and sequentially stacked by one layer.

Each of the plurality of second thin films 16a, 16b, and 16c of FIG. 1 is composed of a semiconductor quantum dot layer having an identical semiconductor quantum dot size.

A self-assembled semiconductor quantum dot layer composed of each of the plurality of second thin films 16a, 16b, and 16c has a hexagonal array structure and a close packed structure.

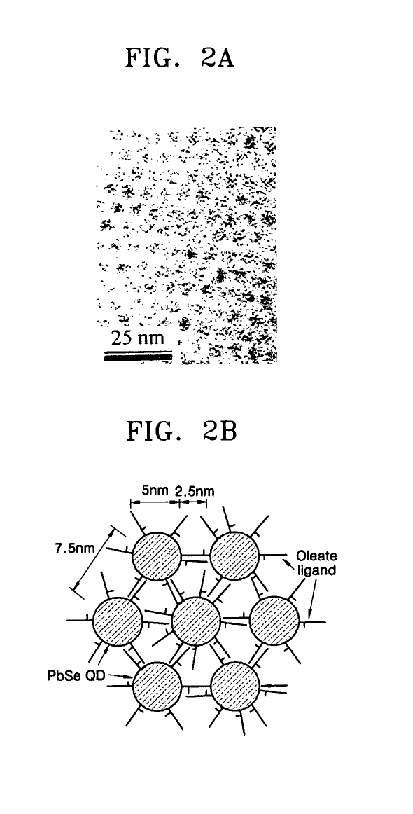

FIG. 2A is a transmission electron microscope (TEM) image illustrating an exemplary semiconductor quantum dot layer used to form the plurality of second thin films 16a, 16b, and 16c.

Specifically, FIG. 2A is a TEM image illustrating a hexagonal array structure of a one-layered self-assembled PbSe quantum dot layer formed by spin-coating a solution of an organic oleate ligand and PbSe quantum dots having an average 5 nm size.

FIG. 2B is a schematic diagram illustrating an alignment state of PbSe quantum dots having a hexagonal array structure in the PbSe quantum dot layer of FIG. 2A.

FIG. 2C is a TEM image illustrating a PbSe quantum dots layer of a hexagonal array structure having a two-layered close packed structure.

FIG. 2D is a schematic diagram illustrating an alignment state of a PbSe quantum dots layer of a hexagonal array structure having a four-layered face centered cubic (FCC) close packed structure.

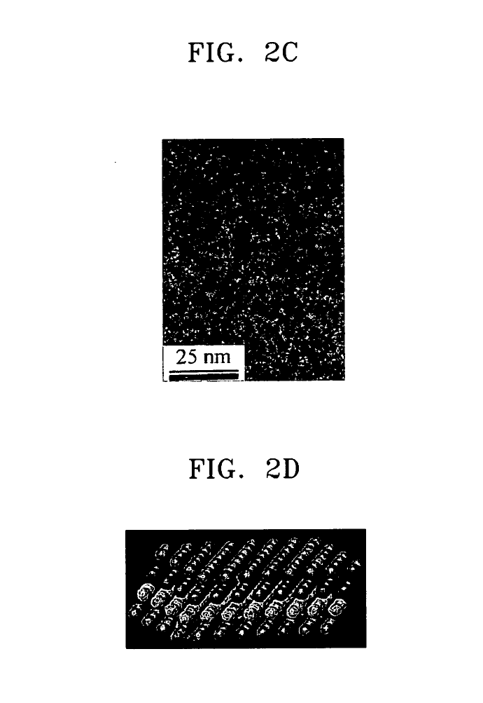

FIG. 3 is a partial perspective view illustrating a structure of an organic-inorganic hybrid nanocomposite thin film 20 for a high-powered and/or broadband photonic device according to another embodiment of the present invention.

Referring to FIG. 3, the organic-inorganic hybrid nanocomposite thin film 20 for a high-powered and/or broadband photonic device according to another embodiment of the present invention comprises a plurality of first thin films 24 composed of a polymer layer formed on a substrate 22, and a plurality of second thin films 26a, 26b, and 26c composed of a self-assembled semiconductor quantum dot layer formed on the first thin film 24, in which the first thin films 24 and the second thin films 26a, 26b, and 26c are alternately and sequentially stacked by one layer.

FIG. 3 illustrates an example that the plurality of second thin films 26a, 26b, and 26c are respectively formed of semiconductor quantum dot layers, each layer having a different semiconductor quantum dot size.

The self-assembled semiconductor quantum dot layer of each of the plurality of second thin films 26a, 26b, and 26c has a hexagonal array structure and a close packed structure.

In exemplary other embodiments of the present invention, a nonpolar polymer thin film is patterned to a predetermined shape using a photolithography process and the like, so as to form a nonpolar polymer thin film pattern having holes, and a spin-coating of a polar semiconductor quantum dot solution is performed so as to fill the holes of the nonpolar polymer thin film pattern with the polar semiconductor quantum dot solution, and a spin-coating of a nonpolar polymer thin film is performed thereon, which are repeatedly performed. As a result, there is provided an organic-inorganic hybrid nanocomposite thin film comprising composite thin films composed of a first pattern of the polymer thin film pattern and a second pattern of a semiconductor quantum dot layer filled inside the holes of the polymer thin film pattern. In the composite thin film, the first pattern and the second pattern are formed on a same plane at a same height level. The composite thin film having the first pattern and the second pattern formed on a same plane, and a polymer layer are alternately and sequentially stacked by one layer, thereby forming an organic-inorganic hybrid nanocomposite thin film according to another embodiment of the present invention.

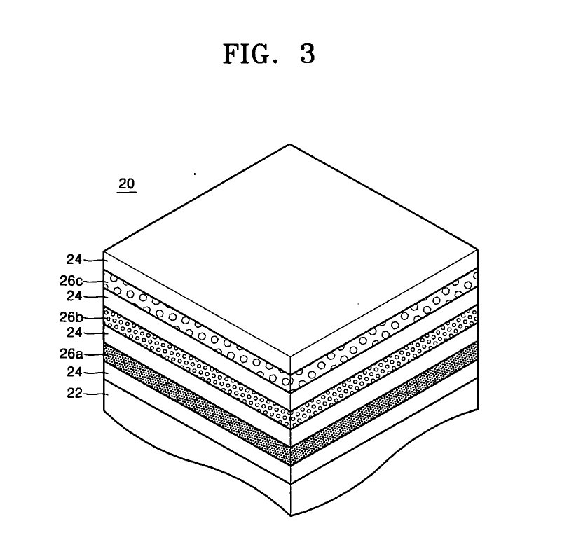

FIG. 4 is a partial perspective view illustrating a structure of an organic-inorganic hybrid nanocomposite thin film 30 for a high-powered and/or broadband photonic device according to another embodiment of the present invention.

Referring to FIG. 4, the organic-inorganic hybrid nanocomposite thin film 30 for a high-powered and/or broadband photonic device according to another embodiment of the present invention comprises a first thin film 34 composed of a polymer layer formed on a substrate 32, and a composite thin film 36 formed on the first thin film 34.

The composite thin film 36 comprises a first pattern 37 composed of a predetermined-shaped polymer thin film pattern having a predetermined-shaped hole 37a exposing an upper surface of the first thin film 34, and a second pattern 38 composed of a semiconductor quantum dot layer filled inside a hole 37a of the first pattern 37. In the composite thin film 36, the first pattern 37 and the second pattern 38 are formed on a same plane at a same height level. The first thin film 34 composed of other polymer layer to cover an upper surface of the composite thin film 36 may be further formed on the composite thin film 36. A semiconductor quantum dot layer forming the second pattern 38 of the composite thin film 36 has a hexagonal array structure and a close packed structure.

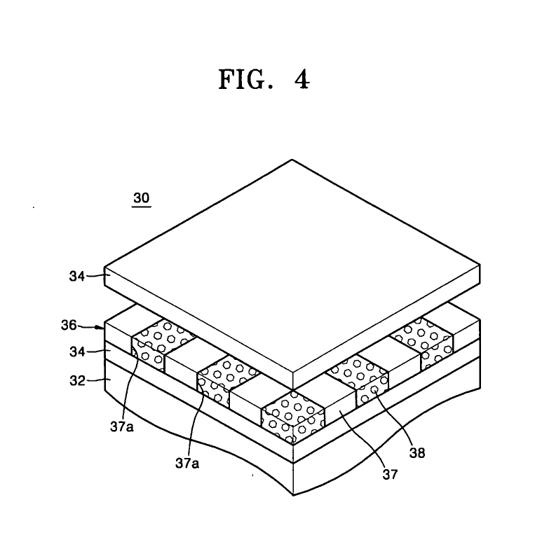

FIG. 5 is a partial perspective view illustrating a structure of an organic-inorganic hybrid nanocomposite thin film 40 for a high-powered and/or broadband photonic device according to another embodiment of the present invention. In FIG. 5, component elements equal to or similar to those of FIG. 4 will be denoted as like reference numerals.

Referring to FIG. 5, the organic-inorganic hybrid nanocomposite thin film 40 for a high-powered and/or broadband photonic device according to another embodiment of the present invention comprises a plurality of first thin films 34 composed of a polymer layer formed on a substrate 42, and a plurality of composite thin films 46a, 46b, and 46c, in which the first thin films 34 and the second thin films 46a, 46b, and 46c are alternately and sequentially stacked by one layer.

Each of the composite thin films 46a, 46b, and 46c comprises a first pattern 37 composed of a predetermined-shaped polymer thin film pattern having a predetermined-shaped hole 37a exposing an upper surface of the first thin film 34, and a second pattern 38 composed of a semiconductor quantum dot layer filled inside a hole 37a of the first pattern 37.

FIG. 5 illustrates an example that in the plurality of second thin films 46a, 46b, and 46c, each second pattern 38 is formed of a semiconductor quantum dot layer, the patterns having a same semiconductor quantum dot size.

A semiconductor quantum dot layer constituting the second pattern 38 has a hexagonal array structure and a close packed structure.

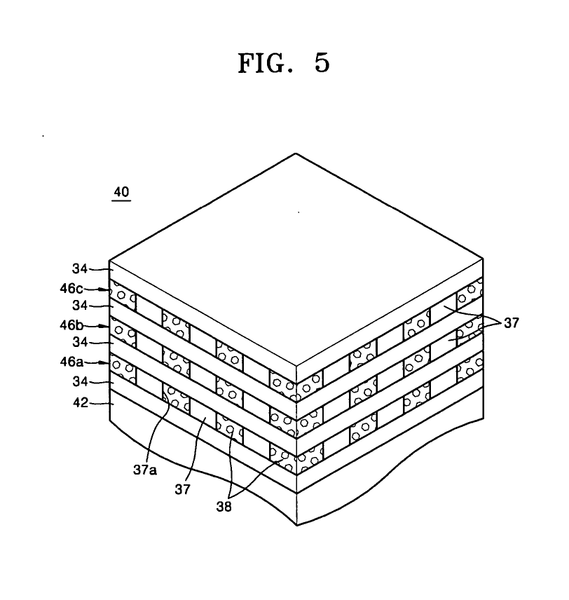

FIG. 6 is a partial perspective view illustrating a structure of an organic-inorganic hybrid nanocomposite thin film 50 for a high-powered and/or broadband photonic device according to another embodiment of the present invention. In FIG. 6, component elements equal to or similar to those of FIG. 5 will be denoted as like reference numerals.

Referring to FIG. 6, the organic-inorganic hybrid nanocomposite thin film 40 for a high-powered and/or broadband photonic device according to another embodiment of the present invention comprises a plurality of first thin films 34 composed of a polymer layer formed on a substrate 52, and a plurality of composite thin films 56a, 56b, and 56c, in which the plurality of first thin films 34 and the plurality of composite thin films 56a, 56b, and 56c are alternately and sequentially stacked by one layer.

Each of the composite thin films 56a, 56b, and 56c comprises a first pattern 37 composed of a predetermined-shaped polymer thin film pattern having a predetermined-shaped hole 37a exposing an upper surface of the first thin film 34, and second patterns 38a, 38b, and 38c composed of a semiconductor quantum dot layer filled inside a hole 37a of the first pattern 37.

FIG. 6 illustrates an example that in the plurality of composite thin films 36, each of the second patterns 38a, 38b, and 38c is formed of a semiconductor quantum dot layer having a different semiconductor quantum dot size.

In the plurality of composite thin films 36, a self-assembled semiconductor quantum dot layer constituting each of the second patterns 38a, 38b, and 38c has a hexagonal array structure and a close packed structure.

In the organic-inorganic hybrid nanocomposite thin films 10, 20, 30, 40, and 50 for a high-powered and/or broadband photonic device according to embodiments of the present invention illustrated in FIGS. 1 and 3 through 6, the substrates 12, 22, 32, 42, and 52 may be formed of flexible polymer substrates to provide a flexibility. Further, after multiple thin films of a stack structure comprising a polymer layer and a semiconductor quantum dot layer are formed on the substrates 12, 22, 32, 42, and 52, the substrates 12, 22, 32, 42, and 52 may be separated therefrom, thereby forming a flexible organic-inorganic hybrid nanocomposite thin film for a high-powered/broadband photonic device.

Hereinafter, specific experiment examples of forming an organic-inorganic hybrid nanocomposite thin film for a high-powered/broadband photonic device according to embodiments of the present invention will be explained. Following examples are provided to explain the present invention more completely, but not intended to confine the scope of the present invention.

### EXAMPLE 1

An oleate ligand-coordinated PbSe quantum dot toluene solution (PbSe quantum dot solution) having a concentration of 2.5 mg/ml and a polymer solution for nano imprint (NIP solution, Zenphotonics, Inc.) are prepared. The PbSe quantum dot solution has a polarity due to an oleate ligand coordinated to a PbSe quantum dot, and an average size of a used PbSe quantum dot is 5 nm or less. The NIP solution is a perfluorinated acrylate-based solvent free resin, and is transparent in an optical communication wavelength region, and has characteristics of a very low viscosity of 10 cP or less, and a nonpolarity.

An NIP solution is supplied on a transparent substrate, for example, a fused silica or indium tin oxide (ITO) glass by a spin coating method, and ultraviolet rays is applied to optically harden a coated NIP solution. A PbSe quantum dot solution is spin-coated thereon at a very low speed, and a remnant solvent is removed inside a vacuum oven.

As described above, FIG. 2A illustrates that a hexagonal array structure of semiconductor quantum dots is formed as one layer by spin-coating a PbSe quantum dot solution having a polarity property on a carbon layer having a nonpolarity property. FIG. 2C is a TEM image illustrating a self-assembled resultant structure and a two-layered close and packed structure composed of semiconductor quantum dots.

The three polymer layers and the three PbSe quantum dot layers are alternately and repeatedly formed by one layer using the method as described above, thereby forming an organic-inorganic hybrid nanocomposite thin film having a high concentration of PbSe quantum dots like the structure as illustrated in FIG. 1.

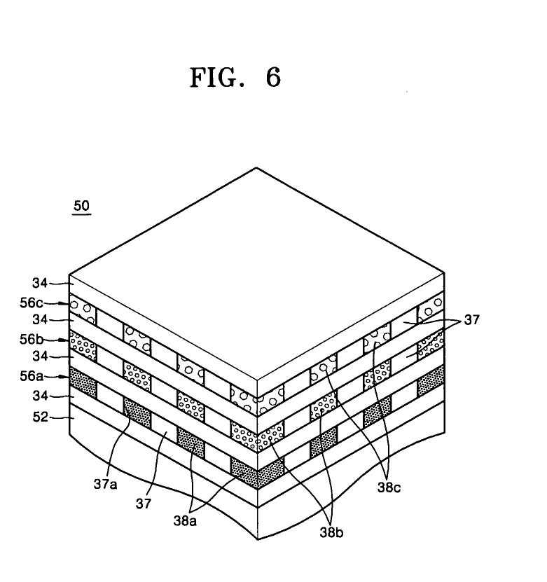

FIG. 7 is a graph illustrating a photoluminescence (PL) intensity characteristic with respect to an organic-inorganic hybrid nanocomposite thin film according to an embodiment of the present invention having a one-layered ((a) of FIG. 7), a two-layered ((b) of FIG. 7), and a three-layered ((c) of FIG. 7) self-assembled PbSe quantum dot layer. In FIG. 7, it is acknowledged that a PL intensity is increased as the number of the PbSe quantum dot layer is increased.

The organic-inorganic hybrid nanocomposite thin film having multiple semiconductor quantum dot layers stacked by performing a spin-coating plural times by the method as explained in Example 1 can increase the number (density) of quantum dots per unit area significantly. In the organic-inorganic hybrid nanocomposite thin film according to embodiments of the present invention, a density of semiconductor quantum dots layers is increased as the number of stack of the semiconductor quantum dots layers is increased, and thus, a PL intensity is linearly increased according thereto. Thus, the organic-inorganic hybrid nanocomposite thin film having multiple-layered semiconductor quantum dot layers stacked is noted very hopefully as a luminescence layer material for a high-powered photonic device.

### EXAMPLE 2

In Example 2, fabrication of a broadband IR LED as one example of fabrication of a photonic device using the organic-inorganic hybrid nanocomposite thin film according to exemplary embodiments of the present invention will be explained.

Three kinds of oleate ligand-coordinated PbSe quantum dot toluene solution having different sizes with a concentration of 2.5 mg/ml (PbSe quantum dot solution I, II, and III) and a conductive polymer solution are prepared. Average diameters of the quantum dots in the three kinds of PbSe quantum dot solutions I, II, and III are respectively 3.5 nm, 4.6 nm, and 5.0 nm.

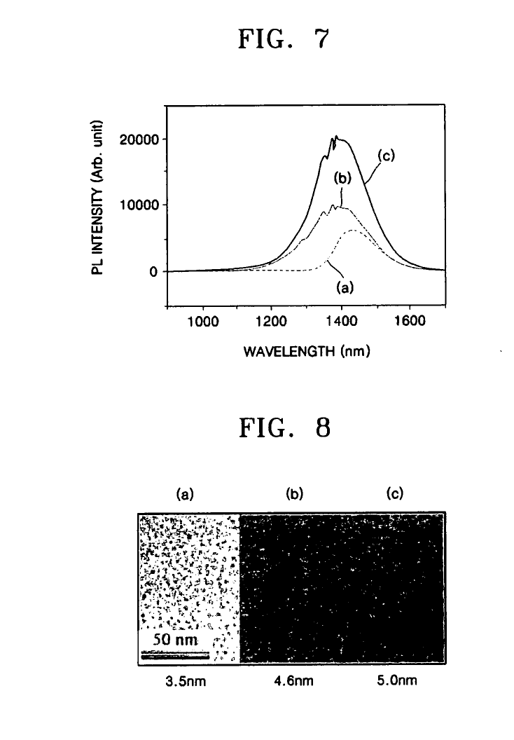

In FIG. 8, (a), (b), and (c) are TEM images examined after spin-coating oleate ligand-coordinated PbSe quantum dot solutions respectively having average diameters of 3.5 nm (quantum dot solution I), 4.6 nm (quantum dot solution II), and 5.0 nm (quantum dot solution III).

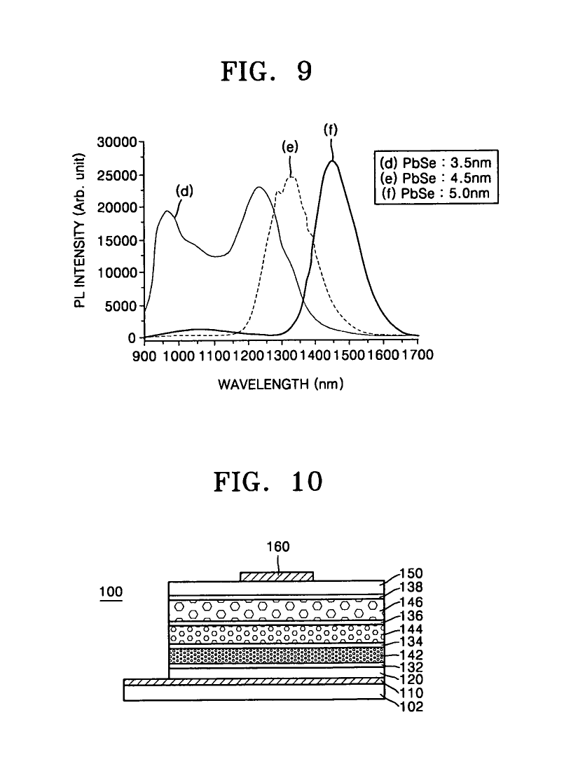

FIG. 9 illustrates PL characteristics in accordance with an average diameter of a PbSe quantum dot. In FIG. 9, photoluminescence is shown in a long wavelength range as an average diameter of a PbSe quantum dot is increased, and it is acknowledged that 200 nm of wavelength transition is occurred in 1.5 nm of diameter difference.

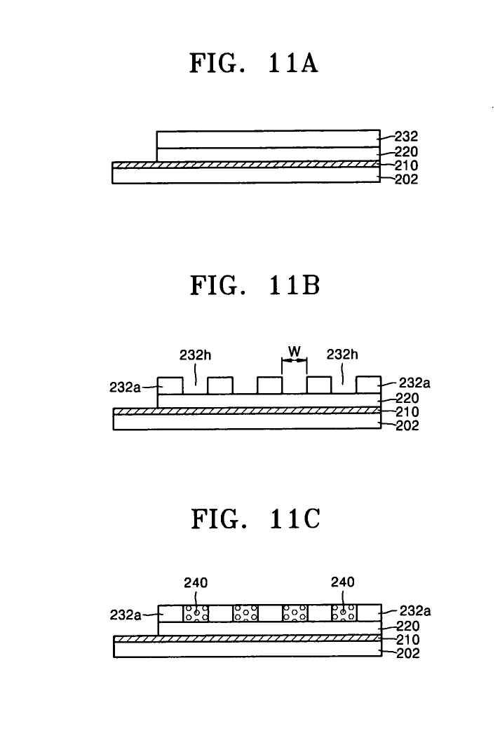

FIG. 10 is a sectional view illustrating a schematic structure of an IR LED 100 fabricated in embodiments of the present invention.

An example of fabricating the IR LED 100 according to the present invention will be explained in reference to FIG. 10. A hole transporting layer 120 is formed on a glass substrate 102 having an ITO anode 110 coated thereon. A poly(ethylene dioxythiphene) (PEDOT) solution is spin-coated and thermally hardened in order to form the hole transmitting layer 120.

An MEH-PPV (poly(2-methhoxy-5-(2-ethylhexyloxy)-1,4-pheneylenevinylene) solution as a polymer luminescence material is spin-coated on the hole transmitting layer 120, and thermally hardened, so as to form a first polymer layer 132. A quantum dot solution I is spin-coated on the first polymer 132 at a very low speed, and a remnant solvent is removed from a vacuum oven, thereby forming a first semiconductor quantum dot layer 142. The MEH-PPV solution is again spin-coated on the first semiconductor quantum dot layer 142, and is thermally hardened, thereby forming a second polymer layer 134. A quantum dot solution II is spin-coated on the second polymer layer 134 at a very low speed, and a remnant solvent is removed from a vacuum oven, thereby forming a second semiconductor quantum dot layer 144. The MEH-PPV solution is again spin-coated on the second semiconductor quantum dot layer 144, and is thermally hardened, thereby forming a third polymer layer 136. A quantum dot solution III is spin-coated on the third polymer layer 136 at a very low speed, and a remnant solvent is removed from a vacuum oven, thereby forming a third semiconductor quantum dot layer 146. The MEH-PPV solution is again spin-coated on the third semiconductor quantum dot layer 146, and is thermally hardened, thereby forming a fourth polymer layer 138.

A hole transmitting layer 150 is formed on the fourth polymer layer 138. A PBD (2-(4-tert-Butylphenyl)-5-(4-biphenylyl)-1,3,4-oxadiazole) solution is spin-coated and thermally hardened so as to form the hole transmitting layer 150. LiF and Al are vacuum-deposited on the hole transmitting layer 150 to form a cathode 160, thereby forming a broadband IR LED.

In order to form an organic-inorganic hybrid nanocomposite thin film having a stack of multiple-layered semiconductor quantum dot layers by performing a spin-coating plural times using the method as described in Example 2, by performing a spin-coating of semiconductor quantum dot solutions respectively having different quantum dot sizes, semiconductor quantum dot layers having different quantum dot sizes are stacked so that a density of the semiconductor quantum dot layer can be controlled desirably. Thus, an IR LED 100 having a luminescence layer composed of an organic-inorganic hybrid nanocomposite thin film formed by the method as described in Example 2 provides characteristics of high power, broad band, high brightness, and high sensibility. Alternatively, the substrate 102 may use a flexible substrate other than the glass substrate, for example, a transparent plastic substrate, thereby providing a flexible photonic device.

### EXAMPLE 3

Another example of a method of fabricating a photonic device using an organic-inorganic hybrid nanocomposite thin film according to exemplary embodiment of the present invention will be explained.

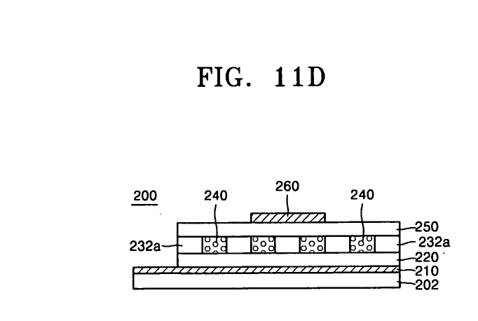

A method of fabricating a photonic device 200 according to an embodiment of the present invention will be explained in reference to FIGS. 11A through 11D.

An oleate ligand-coordinated PbSe quantum dot solution (semiconductor quantum dot solution) having a concentration of 2.5 mg/ml, a PEDOT solution, an MEH-PPV solution, and a PBD solution are prepared.

As illustrated in FIG. 11A, an ITO anode 210 is formed on a glass substrate 202. The PEDOT solution is spin-coated on the anode 210, and thermally hardened, thereby forming a hole transmitting layer 220. The MEH-PPV solution as a polymer luminescence material is spin-coated on the hole transmitting layer 220, and thermally hardened, thereby forming a polymer layer 232.

Referring to FIG. 11B, the polymer layer 232 is patterned using a photolithography process, thereby forming a rectangular-shaped hole 232h having a width W of 500 μm in one direction (that is, a polymer layer pattern 232a, in which a plurality of holes 232h having a plane area size of 500 μm×500 μm are aligned in a periodical interval). At this time, O₂-reactive ion etching is used to etch the polymer layer 232.

Referring to FIG. 11C, a PbSe quantum dot solution is spin-coated on the first polymer layer pattern 232a, so as to fill a self-assembled PbSe quantum dot inside the hole 232h, and a remnant solvent is removed from a vacuum oven, thereby forming a semiconductor quantum dot layer 240.

Referring to FIG. 11D, a PBD solution is spin-coated on the first polymer layer pattern 232a and the semiconductor quantum dot layer 240 to cover them concurrently, and is thermally hardened, thereby forming an electron transmitting layer 250. Then, LiF and Al are vacuum-deposited thereon so as to form a cathode 260, thereby forming a photonic device 200.

After a polarity polymer thin film is formed on a nonpolarity polymer thin film using the method as described in Example 3, the polarity polymer thin film is etched into a predetermined shape so as to form a hole. A photonic device 200 having a luminescence layer composed of an organic-inorganic hybrid nanocomposite thin film formed by filling a semiconductor quantum dot into the hole according to an embodiment of the present invention provides characteristics of high power, broad band, high brightness, and high sensitivity. Further, by employing a flexible substrate other than a glass substrate, for example a transparent plastic substrate as the substrate 202, a flexible photonic device can be provided.

The organic-inorganic hybrid nanocomposite thin film for a photonic device according to an embodiment of the present invention comprises a stack structure of a polymer layer and a self-assembled organic ligand-coordinated semiconductor quantum dot layer on the polymer layer, or a first composite thin film including a first polymer layer pattern having a first hole, and an organic ligand-coordinated first semiconductor quantum dot layer pattern filling the first hole. The semiconductor quantum dot has a closely packed and hexagonally arrayed structure three-dimensionally, and has a face centered cubic (FCC) stack structure. The organic-inorganic hybrid nanocomposite thin film for a photonic device of the present invention is formed by preparing a previously mixed semiconductor quantum dot solution, and performing a spin coating of the solution, thereby forming a multiple-layered semiconductor quantum dot layer structure composed of a plurality of layers. Further, the organic-inorganic hybrid nanocomposite thin film for a photonic device of the present invention can be used as a luminescence layer of a photonic device, thereby realizing a photonic device, such as an LED, an optical receiver, an optical sensor, and sun battery of a high power, a broad band, a high brightness, and a high sensibility. Furthermore, a flexible photonic device can be provided by employing a flexible substrate, or by forming the organic-inorganic hybrid nanocomposite thin film for a photonic device of the present invention and removing the substrate.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic-inorganic hybrid nanocomposite thin film for a photonic device composed of a stack structure comprising a polymer layer and an organic ligand-coordinated semiconductor quantum dot layer self-assembled on the polymer layer.

2. The organic-inorganic hybrid nanocomposite thin film of claim 1, wherein the polymer layer and the semiconductor quantum dot layer have different properties selected from a polarity and a nonpolarity respectively.

3. The organic-inorganic hybrid nanocomposite thin film of claim 1, wherein the stack structure comprises a plurality of polymer layers and a plurality of semiconductor quantum dot layers, which are alternately and sequentially stacked by one layer.

4. The organic-inorganic hybrid nanocomposite thin film of claim 3, wherein the plurality of semiconductor quantum dot layers have a same size of quantum dots.

5. The organic-inorganic hybrid nanocomposite thin film of claim 3, wherein the plurality of semiconductor quantum dot layers have at least two semiconductor quantum dot layers, quantum dots of which have different sizes.

6. An organic-inorganic hybrid nanocomposite thin film for a photonic device composed of a first composite thin film comprising a first polymer layer pattern having a first hole, and an organic ligand-coordinated first semiconductor quantum dot layer pattern filling the first hole.

7. The organic-inorganic hybrid nanocomposite thin film of claim 6, wherein the first polymer layer pattern and the first semiconductor quantum dot layer pattern are formed on a same plane at a same height level.

8. The organic-inorganic hybrid nanocomposite thin film of claim 6, further comprising a first polymer thin film formed on the first composite thin film to cover the first polymer layer pattern and the first semiconductor quantum dot layer pattern concurrently.

9. The organic-inorganic hybrid nanocomposite thin film of claim 8, further comprising a second composite thin film formed on the first polymer thin film and opposite to the first composite thin film, and comprising a second polymer layer pattern having a second hole, and an organic ligand-coordinated second semiconductor quantum dot layer pattern filling the second hole.

10. The organic-inorganic hybrid nanocomposite thin film of claim 9, wherein the first semiconductor quantum dot layer pattern and the second semiconductor quantum dot layer pattern have a same size of quantum dots.

11. The organic-inorganic hybrid nanocomposite thin film of claim 9, wherein the first semiconductor quantum dot layer pattern and the second semiconductor quantum dot layer pattern have different sizes of quantum dots respectively.

12. A photonic device comprising:
a first electrode;
a second electrode; and
a hole transmitting layer, a luminescence layer, and an electron transmitting layer, which are sequentially stacked between the first electrode and the second electrode, in which the luminescence layer is composed of the organic-inorganic hybrid nanocomposite thin film of claim 1.

13. The photonic device comprising:
a first electrode;
a second electrode;
a hole transmitting layer, a luminescence layer, and an electron transmitting layer, which are sequentially stacked between the first electrode and the second electrode, in which the luminescence layer is composed of the organic-inorganic hybrid nanocomposite thin film of claim 6.

14. A method of forming an organic-inorganic hybrid nanocomposite thin film for a photonic device comprising:
forming a polymer layer on a substrate;
spin-coating an organic ligand-coordinated semiconductor quantum dot solution on the polymer layer, thereby forming a self-assembled semiconductor quantum dot layer on the polymer layer.

15. The method of claim 14, further comprising repeatedly performing the operation of forming the polymer layer and the operation of forming the semiconductor quantum dot layer, thereby forming a stack structure comprising a plurality of polymer layers and a plurality of semiconductor quantum dot layers, which are alternately and sequentially stacked by one layer.

16. The method of claim 15, wherein the plurality of semiconductor quantum dot layers have a same size of quantum dots.

17. The method of claim 15, wherein the plurality of semiconductor quantum dot layers have at least two semiconductor quantum dot layers, quantum dots of which have different sizes.

18. The method of claim 14, further comprising removing the substrate from the polymer layer.

19. The method of claim 14, wherein the substrate is formed of fused silica, glass, or plastic.

20. A method of forming an organic-inorganic hybrid nanocomposite thin film for a photonic device comprising:
forming a first polymer layer on a substrate;
patterning the first polymer layer, thereby forming a first polymer layer pattern having a predetermined-shaped first hole; and
spin-coating an organic ligand-coordinated semiconductor quantum dot solution on a first polymer layer pattern, thereby forming a first semiconductor quantum dot layer pattern inside the first hole.

21. The method of claim 20, further comprising forming a first polymer thin film covering the first polymer layer pattern and the first semiconductor quantum dot layer pattern concurrently.

22. The method of claim 21, further comprising:
forming a second polymer layer on the first polymer thin film;
patterning the second polymer layer, thereby forming a second polymer layer pattern having a predetermined-shaped second hole; and
spin-coating an organic ligand-coordinated semiconductor quantum dot solution on the second polymer layer pattern, thereby forming a second semiconductor quantum dot layer pattern inside the second hole.

23. The method of claim 22, wherein the first semiconductor quantum dot layer pattern and the second semiconductor quantum dot layer pattern are formed to have a same size of quantum dots.

24. The method of claim 22, wherein the first semiconductor quantum dot layer pattern and the second semiconductor quantum dot layer pattern are formed to have different sizes of semiconductor quantum dots respectively.
